(19) United States
(12) Patent Application Publication
(10) Pub. No.: US 2015/0028913 A1
(43) Pub. Date: Jan. 29, 2015

(54) TESTING APPARATUS AND TESTING METHOD

(71) Applicant: Siliconware Precision Industries Co., Ltd., Taichung (TW)

(72) Inventors: Kuang-Ching Fan, Taichung (TW); Hsin-Hung Lee, Taichung (TW)

(73) Assignee: Siliconware Precision Industries Co., Ltd., Taichung (TW)

(21) Appl. No.: 14/074,187

(22) Filed: Nov. 7, 2013

(30) Foreign Application Priority Data
Jul. 24, 2013 (TW) 102126419

(51) Int. Cl. G01R 31/26

(52) U.S. Cl. CPC G01R 31/2601
USPC 324/762.01

(57) ABSTRACT

The present invention proposes a testing method for testing a semiconductor element, including: providing a semiconductor element having a first surface on which a first testing area is formed and a second surface on which a second testing surface is formed; placing the semiconductor element on a plane surface, allowing any one of the first surface and the second surface to be in no parallel to the plane surface; and electrically connecting a testing apparatus to the first testing area and the second testing area of the semiconductor element. The semiconductor element is placed in a non-horizontal manner on the testing apparatus, which makes contact with the two opposing surfaces of the semiconductor element in a horizontal way without directly exerting a downward force against the surface of the semiconductor element, thereby preventing the semiconductor element from damages.

### BACKGROUND OF THE INVENTION

1. Field of the Invention

The present invention relates to testing methods, and, more particularly, to a testing apparatus for testing a semiconductor element and a testing method thereof.

2. Description of the Prior Art

As the demand for high variations and low-profile electronic products is growing nowadays, it is necessary to integrate more electronic elements on a single area, therefore 3D-IC technology has been developed.

3D-IC technology utilizes three dimensional stacking to incorporate substrates, and chips of different functionalities and materials, then using Through-Silicon Via (TSV) technology, so as to reduce the length of conductive traces, thereby reducing resistance and chip area, hence having the advantages such as low profile, high integration, high efficiency and high energy efficiency, and low production cost.

Since for 3D-IC or 2.5D-IC, electrical functional test is a key to determine whether the product can go to the next phase of mass production. Moreover electrical functional test is particularly important for TSV semiconductor element, and the test is divided into chip probe (CP) and final test (FT).

As shown in FIGS. 1A and 1B, a wafer substrate 9 assembled with a chip 8 undergoes a CP test. A testing element 7 (i.e., a chip 8 and a wafer substrate 9 having a silicon via 90) is placed on a testing apparatus 1 having a base 10 and a lid 11 tightly connected through air pressure, allowing the base 10, the testing element 7 and the lid to be connected tightly such that the pogo-pin 110 of the lid 11 is electrically connected to the electrical points 91 on the upper side of the wafer substrate 9, and the conductive traces 100 and the conductive bumps 101 to be electrically connected to the electrical contacts 92 on the lower side of the wafer substrate 9, allowing another pogo-pin (not shown) to carry out testing procedure, forming double (upper and lower side) testing circuits.

However, since the wafer substrate 9 having the silicon via 90 generally is quite thin, around 10 to 180 μm, when placed horizontally during CP, the wafer substrate 9 can be easily damaged when subjected to high pressured air.

Moreover, a protective layer (not shown) is formed on the upper side of the wafer substrate 9 to cover electrical points 91, and is removed after the lower side of the wafer substrate 9 is bound with the chip. Therefore, CP to test the electrical functionality is performed after the chip 8 is bound with the wafer substrate 9 having the silicon via 90, however the yield of forming silicon via 90 may cause the testing element 7 (i.e., the assembled silicon substrate 9 and chip 8) to fail, thereby increasing the fabricating cost.

Therefore, there is an urgent need to find solutions to solve the foregoing problems.

### SUMMARY OF THE INVENTION

In light of the foregoing drawbacks of the prior art, the present invention proposes a testing method for testing a semiconductor elements, comprising: providing a semiconductor element having a first surface on which a first testing area is formed and a second surface on which a second testing surface is formed; placing the semiconductor on a plane surface, allowing any one of the first surface and the second surface to be in no parallel to the plane surface; and electrically connecting the testing apparatus to the first testing area and the second testing area of the semiconductor element and testing the semiconductor element.

In an embodiment, the semiconductor element has an interposer having a conductive via, or a plurality of interposers having conductive vias.

In an embodiment, through the first surface of the semiconductor element, the semiconductor element is mounted on a carrier in a manner that the first surface of the semiconductor element is disposed on the carrier, and the carrier has an opening to expose the first testing area.

In an embodiment, the method further comprises: mounting the semiconductor element on the carrier that has an opening to expose the first testing area, wherein a protective layer is formed on the second surface; forming a plurality of holes on the protective layer surrounding the second testing area; forming an adhesive layer on the protective layer; and removing the adhesive layer, and removing the protective layer, through the holes, to expose the second testing area.

In an embodiment, the semiconductor elements is constituted by a plurality of semiconductor units, and having a plurality of cutting areas corresponding to the holes, wherein each of the cutting areas is disposed between any two of the semiconductor units. In an embodiment, the testing method further comprises, prior to forming the adhesive layer, performing an exposure and development process on the protective layer.

In an embodiment, the semiconductor element is vertically mounted on a frame.

The present invention further proposes a testing apparatus for testing a semiconductor element, comprising: at least one frame placed on a plane surface, for a semiconductor element to be disposed thereon, allowing any one of two opposing surfaces of the semiconductor element to be in no parallel to the plane surface; a testing apparatus for electrically connecting the two opposing surfaces of the semiconductor element and testing the semiconductor element.

In an embodiment, the testing apparatus comprises a three-dimensional positioning apparatus or at least two testing apparatus.

In an embodiment, the any one of the opposing first and second surfaces of the semiconductor element and the plane surface have an included angle ranging from 15 to 90 degrees.

In summary, according to the testing apparatus and testing method of the present invention, the semiconductor element is placed in a non-horizontal manner on the testing apparatus, therefore during testing, the testing device makes contact with the two opposing surfaces of the semiconductor element in a horizontal way without directly exerting a downward force against the surface of the semiconductor element, preventing the semiconductor element being damaged.

Moreover, placing the semiconductor element using this manner allows the single semiconductor element to be tested before CP, such as testing the TSV semiconductor element to eliminate those that showed low yield of the TSV, thereby ensuring the quality of semiconductor elements before the stacking process.

### BRIEF DESCRIPTION OF THE DRAWINGS

The present invention can be more fully understood by reading the following detailed description of the preferred embodiments, with reference made to the accompanying drawings, wherein:

FIGS. 1A and 1B are cross-sectional schematic views of a conventional testing apparatus and testing method for testing a semiconductor element;

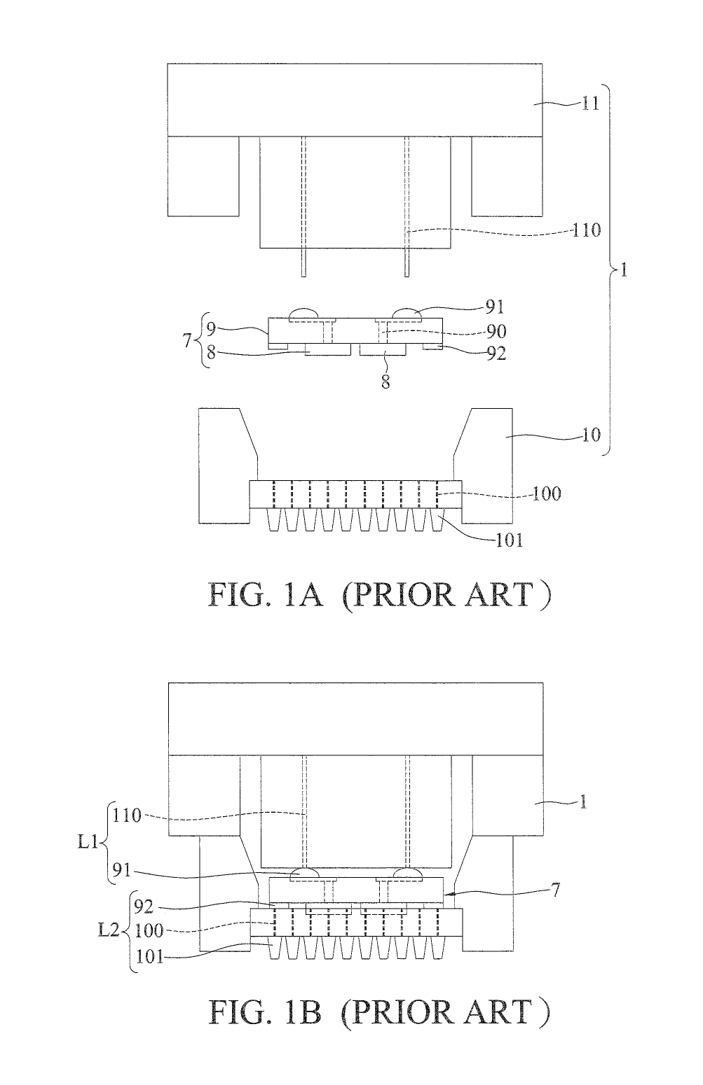

FIG. 2 is the 3D schematic view illustrating a testing method according to the present invention;

FIG. 2′ is the cross-sectional schematic view showing the installation of a semiconductor element in accordance with the testing method of the present invention;

FIGS. 3A to 3D are the cross-sectional schematic views showing the pre-procedures before the installation of the semiconductor element in accordance with the testing method of the present invention package; wherein FIG. 3B′ is the top view of FIG. 3B, and FIG. 3D′ is the top view of FIG. 3D; and

FIG. 4 is the 3D view of a testing apparatus according to the present invention.

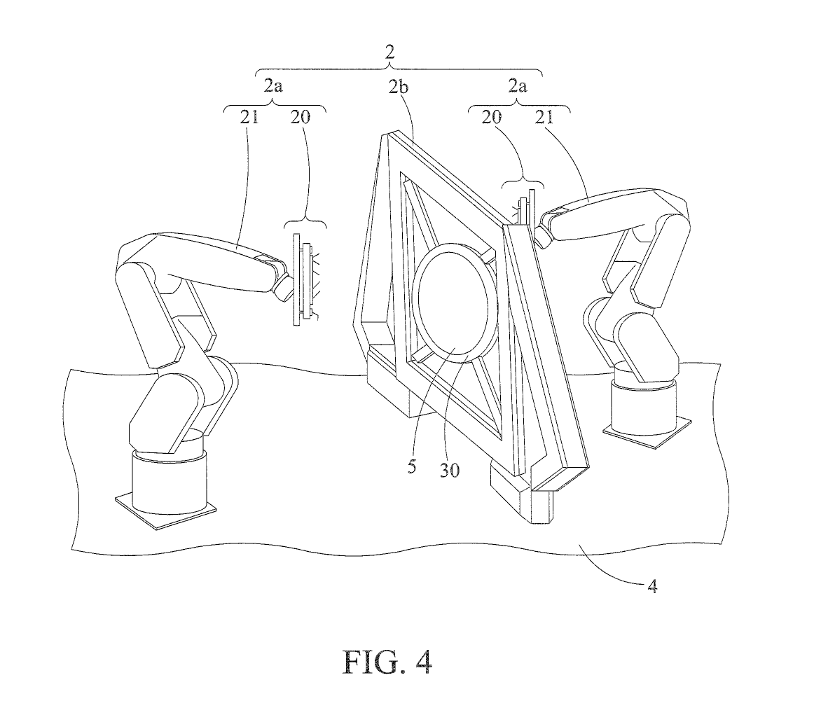

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

It is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements. In addition, words, such as “on”, “top” and “a”, are used to explain the preferred embodiment of the present invention only and should not limit the scope of the present invention.

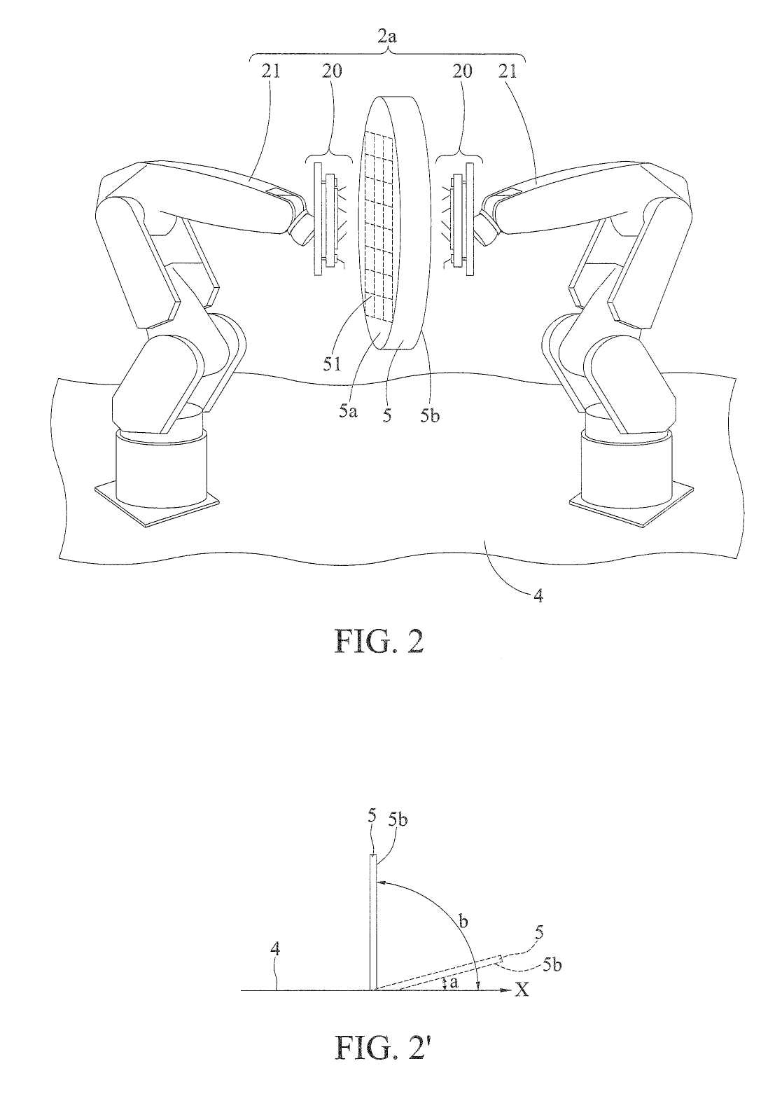

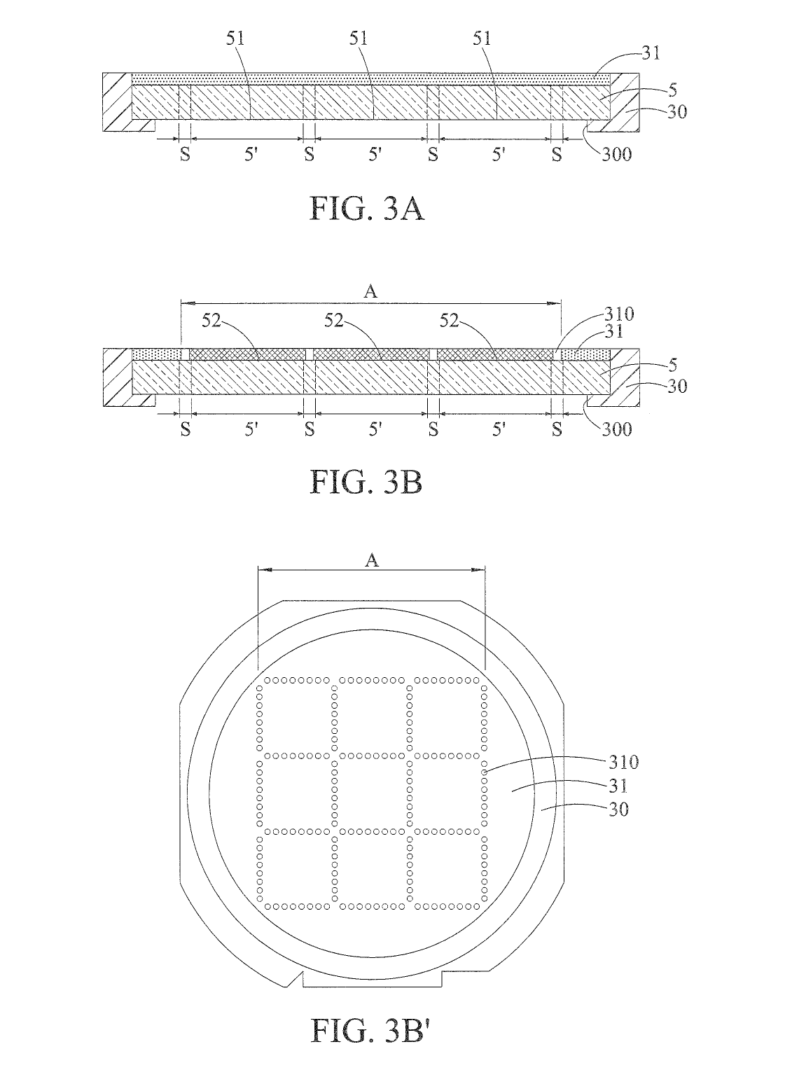

FIG. 2 is the 3D schematic view of a testing method according to the present invention, and, more specifically, to a testing method for a wafer interposer having TSV.

As shown in FIG. 2, the first step is to provide a semiconductor element 5 having a first surface 5a on which a first testing area 51 is formed and an opposing second surface 5b on which a second testing area (not shown) is formed.

Subsequently, the semiconductor element 5 is vertically mounted on a plane surface 4, allowing the first surface 5a and the second surface 5b to be parallel to each other, and an angle ranging from 15 to 90 degrees is formed between any one of the first and second surfaces 5a and 5b of the semiconductor element 5 and the plane surface 4. As shown in FIG. 2′, an angle a represents 15 degrees, and an angle b represents 90 degrees.

In an embodiment, the plane surface 4 is the surface of the machine or ground floor, but is not limited to the foregoing examples.

Then, in the testing process, a testing apparatus 2a is electrically connected to the first testing area 51 and the second testing area of the semiconductor element 5. In an embodiment, the testing apparatus 2a comprises two testing elements 20 and a three-dimensional positioning apparatus 21.

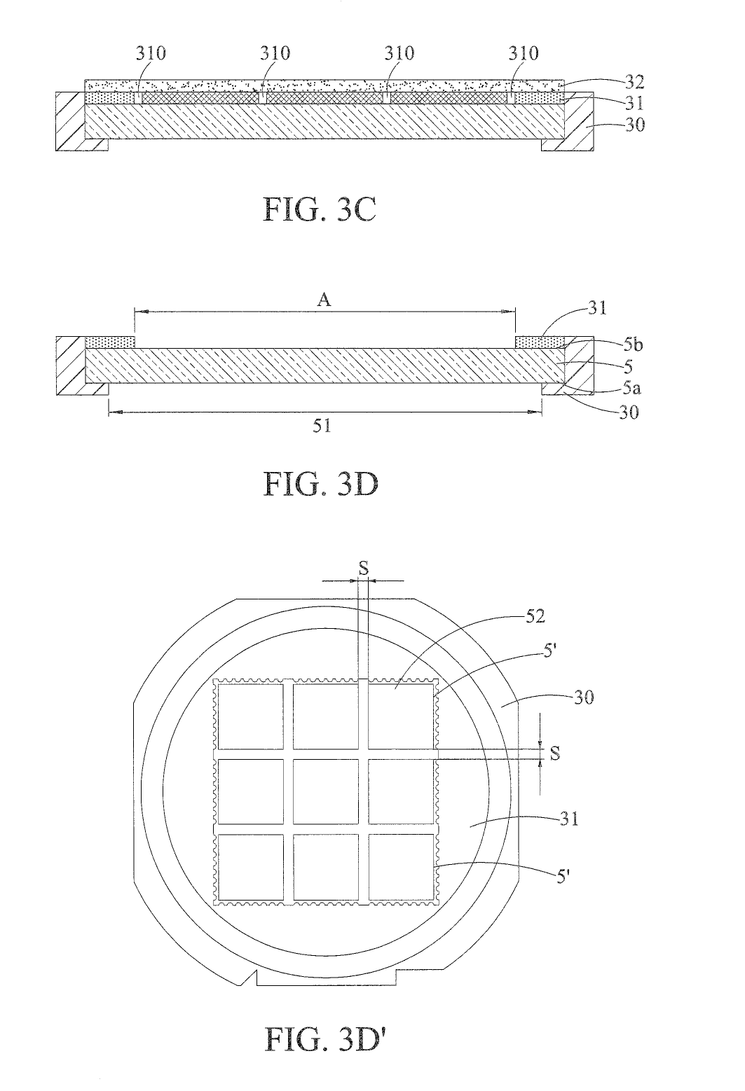

FIGS. 3A to 3D show the pre-procedures before the installation of the semiconductor element in accordance with the testing method of the present invention.

As shown in FIG. 3A, through its first surface 5a the semiconductor element 5 is mounted on a carrier 30 having an opening 300 to expose the first testing area 51. A protective layer 31 is formed on the second surface 5b of the semiconductor element 5.

In an embodiment, the semiconductor element 5 is constituted by a plurality of semiconductor units, and a plurality of cutting areas S, each of which is formed between any two of the semiconductor units.

Moreover, the semiconductor unit 5 is an interposer having a conductive via, more specifically it is a wafer interposer having a TSV. In other embodiments, the semiconductor element 5 is an interposer having a plurality of conductive vias after cutting process.

As shown in FIGS. 3B and 3B′, a plurality of holes 310 are formed on the protective layer 31 surrounding the periphery of the second testing area 52. Subsequently, processes such as an exposure and development process are performed on the protective layer 31.

In an embodiment, the holes 310 are formed corresponding to the cutting area S, to expose an area A of the second testing area 52 in latter processes.

More specifically, the exposure and development process is performed on the protective layer 31 corresponding to the area A of the second testing area 52.

As shown in FIG. 3C, an adhesive layer 32 is formed on the protective layer 31.

As shown in FIG. 3D, an adhesive layer 32 is removed, along with the protective layer 31, to expose the area A of the second testing area 52.

According to the above mentioned pre-procedure, the semiconductor element 5 can be mounted on the carrier 30 through its first surface 5a. The opening 300 of the carrier 30 is formed to expose the first testing area 51.

Accordingly, the present invention provides a solution that, during the testing process, the testing apparatus 2a makes contact with the first surface 5a or the second surface 5b of the semiconductor element 5 in a horizontal way, eliminating the need to vertically exerting downward force against the first surface 5a or the second surface 5b of the semiconductor element 5, preventing damages on the semiconductor element 5 caused by the downward vertical force.

Moreover, the vertical placement of the semiconductor element 5 in the testing method disclosed according to the present invention allows tests to be carried out simultaneously on the first surface 5a and the second surface 5b, eliminating the need in conventional technology in which the two opposing surfaces are tested after chips are stacked. As a result, it is possible to test the semiconductor element 5 prior to CP and any semiconductor element of unsatisfactory test result, such as low yield of TSV, can be eliminated, ensuring the overall quality of semiconductor element 5 before stacking process, thereby reducing the percentage of unsatisfactory final products after CP.

The above mentioned frame 2b is placed on a plane surface 4 for the semiconductor element to be mounted thereon, allowing an angle ranging from 15 to 90 degrees to be formed between the opposing two surfaces of the semiconductor element 5 and the plane surface 4. The frame 2b can adopt different shapes and models, such as being able to rotate for the convenience of having access of the semiconductor element 5 during testing process, however it is not limited to a particular type.

In summary, the testing apparatus and the testing method disclosed according to the present invention utilize vertical or beveled placement of semiconductor elements to prevent the semiconductor elements to be damaged, thereby ensuring a satisfactory quality of semiconductor elements before stacking process.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A testing apparatus for a semiconductor element, comprising:
at least one frame disposed on a plane surface for a semiconductor element to be disposed thereon, allowing any one of two opposing surfaces of the semiconductor element to be in no parallel to the plane surface; and
a testing apparatus for electrically connecting the two opposing surfaces of the semiconductor element and testing the semiconductor element.

2. The testing apparatus of claim 1, wherein the testing apparatus comprises a three-dimensional positioning apparatus.

3. The testing apparatus of claim 1, wherein the testing apparatus comprises at least two testing elements.

4. The testing apparatus of claim 1, wherein the any one of the two opposing surfaces of the semiconductor element and the plane surface angle have an included angle ranging from 15 to 90 degrees.

5. A testing method for a semiconductor elements comprising:
providing a semiconductor element having a first surface on which a first testing area is formed and a second surface on which a second testing surface is formed;
placing the semiconductor element on a plane surface, allowing any one of the first surface and the second surface to be in no parallel to the plane surface; and
electrically connecting a testing apparatus to the first testing area and the second testing area of the semiconductor element and testing the semiconductor element.

6. The testing method of claim 5, wherein the testing apparatus comprises a three-dimensional positioning apparatus.

7. The testing method of claim 5, wherein the testing apparatus comprises at least two testing elements.

8. The testing method of claim 5, wherein the semiconductor element is an interposer having conductive vias.

9. The testing method of claim 5, wherein the semiconductor element includes a plurality of interposers having conductive vias.

10. The testing method of claim 5, wherein the semiconductor element is mounted on a carrier in a manner that the first surface of the semiconductor element is disposed on the carrier, and the carrier has an opening to expose the first testing area.

11. The testing method of claim 5, further comprising:
mounting the semiconductor element on a carrier in a manner that the first surface of the semiconductor element is disposed on the carrier, wherein the carrier has an opening to expose the first testing area, and the second surface of the semiconductor element has a protective layer;
forming a plurality of holes on the protective layer surrounding the second testing area;
forming an adhesive layer on the protective layer; and
removing the adhesive layer, and removing the protective layer, through the openings, to expose the second testing area.

12. The testing method of claim 11, wherein the semiconductor element is constituted by a plurality of semiconductor units, and has a plurality of cutting areas corresponding to the holes, any one of the cutting areas being disposed between any two of the semiconductor units.

13. The testing method of claim 11, further comprising, prior to forming the adhesive layer, performing an exposure and development process on the protective layer.

14. The testing method of claim 5, wherein the semiconductor element is mounted on a frame and the frame is placed on the plane surface.

15. The testing method of claim 5, wherein the any one of the first surface and the second surface of the semiconductor element and the plane surface have an included angle ranging from 15 to 90 degrees.
